(19) United States
(12) Patent Application Publication
(10) Pub. No.: US 2025/0194275 A1
(43) Pub. Date: Jun. 12, 2025

(54) PHOTOELECTRIC SENSOR AND FABRICATION METHODS THEREOF

(71) Applicants: SEMICONDUCTOR MANUFACTURING NORTH CHINA (BEIJING) CORPORATION, Beijing (CN); SEMICONDUCTOR MANUFACTURING INTERNATIONAL (BEIJING) CORPORATION, Beijing (CN); SEMICONDUCTOR MANUFACTURING INTERNATIONAL (SHANGHAI) CORPORATION, Shanghai (CN)

(72) Inventors: Jiuzhou ZHU, Beijing (CN); Xiaoping LI, Beijing (CN); Jianjun LI, Beijing (CN); Zhuo YIN, Beijing (CN)

(21) Appl. No.: 18/968,802

(22) Filed: Dec. 4, 2024

(30) Foreign Application Priority Data
Dec. 7, 2023 (CN) 202311676129.X

(51) Int. Cl. H10F 39/00

(52) U.S. Cl. CPC H10F 39/8057; H10F 39/024; H10F 39/806

(57) ABSTRACT

A photoelectric sensor includes a base substrate having a light-receiving surface and a photosensitive pixel area that includes a plurality of pixel unit areas distributed in a matrix. Each pixel unit area is divided into a plurality of subunit areas in an array arrangement. A plurality of light-shielding structures penetrates a portion of a thickness of the base substrate on a side of the light-receiving surface, and is located in the base substrate between adjacent pixel unit areas and between adjacent subunit areas. A plurality of light-splitting structures penetrates a portion of the thickness of the base substrate on the side of the light-receiving surface, and is distributed in the plurality of subunit areas in a one-to-one correspondence. An extending direction of each light-splitting structure of the plurality of light-splitting structures has an acute angle with a row or column direction of the array arrangement.

### CROSS-REFERENCE TO RELATED APPLICATION

This application claims the priority of Chinese Patent Application No. 202311676129.X, filed on Dec. 7, 2023, the entire content of which is incorporated herein by reference.

### FIELD OF THE DISCLOSURE

The present disclosure generally relates to the field of semiconductor fabrication technology and, more particularly, relates to photoelectric sensor and fabrication methods thereof.

### BACKGROUND

Photoelectric sensor is a device converting light signals to electrical signals. Its working principle is based on the photoelectric effect. The photoelectric effect is the phenomenon when a light shines on certain substance, electrons in the substance absorb the energy of the photons and generate corresponding electrical effects.

For instance, charge-coupled device (CCD) image sensors and complementary metal-oxide-semiconductor (CMOS) image sensors (CIS) use photoelectric-conversion functions to convert optical images into electrical signals and then send out digital images. Currently, they are widely used in digital cameras and other electronic optical devices. The time of flight (ToF) distance sensor projects a modulated infrared light source onto an object, person, or scene. Then, the reflected light is captured by the ToF sensor. This sensor measures the light intensity and the phase difference received by each pixel. Consequently, a highly reliable depth image and a grayscale entire-scene image are obtained. This technique can be applied to various distance measurement scenarios, such as autonomous driving, sweeping robots, virtual reality (VR), or augmented reality (AR) modeling.

### SUMMARY OF THE DISCLOSURE

Embodiments of the present disclosure provide a photoelectric sensor. The photoelectric sensor includes a base substrate having a light-receiving surface and a photosensitive pixel area, the photosensitive pixel area containing a plurality of pixel unit areas distributed as a matrix, and each pixel unit area being divided into a plurality of subunit areas arranged as arrays. The photoelectric sensor further includes a light-shielding structure that penetrates a portion of the thickness of the base substrate on one side of the light-receiving surface. The light-shielding structure is located between the adjacent pixel unit areas and in the base substrate between the adjacent subunit areas. A light-splitting structure penetrates a portion of the thickness of the base substrate on one side of the light-receiving surface. The light-splitting structures are distributed one-to-one in each subunit area. An extending direction of each light-splitting structure has an acute angle with the row or column direction of the array arrangement.

Optionally, each pixel unit area has four subunit areas arranged as an array and the light-shielding structures between the four subunit areas intersect vertically; the extending direction of each light-splitting structure has an acute angle with the extending direction of the light-shielding structure inside the pixel unit area.

Optionally, in each pixel unit area, all extensional directions of light-splitting structures cross the intersections of light-solation structures inside the pixel unit area.

Optionally, the pixel unit areas have a preset light-receiving area at the intersection of light-shielding structures located inside it and covers the partial area of the four subunit areas located near the intersection; in each pixel unit area, the light-splitting structure extends to the light-receiving area.

Optionally, in each pixel unit area, the intersection of the internal light-shielding structures is at the center point of the pixel unit area.

Optionally, the shape of the light-splitting structure is a long strip.

Optionally, the length of the light-splitting structure is 200 nm to 600 nm; the width of the light-splitting structure is 100 nm to 300 nm.

Optionally, the angle between the extending direction of the light-splitting structure and the row or column direction of the array arrangement is 30° to 60°.

Optionally, the angle between the extending direction of the light-splitting structure and the row or column direction of the array arrangement is 45°.

Optionally, the light-splitting and the light-shielding structures are made of the same material.

Embodiments of the present disclosure also provide a method for forming a photoelectric sensor. The method includes: providing a base substrate with a light-receiving surface and the photosensitive pixel area, the photosensitive pixel area including a plurality of pixel unit areas distributed as a matrix. On the light-receiving surface of a light-transmitting layer, the light-transmitting layer including a plurality of lens layers in a one-to-one correspondence related to the pixel unit areas, the lens layers covering the light-receiving surface of the pixel unit areas, and the lens layers being used to focus light in the pixel unit areas.

Optionally, in the steps of providing the base substrate, each pixel unit area has four subunit areas arranged as an array; in the step of forming a splitting structure of the base substrate that penetrates a partial thickness of one side of the light-receiving surface, the extending direction of each splitting structure has an acute angle with the extending direction of the boundary line.

Optionally, in the step of forming the light-splitting structure that penetrates the portion of the thickness of the base substrate on one side of the light-receiving surface, in each pixel unit area, the extending direction of the light-splitting structure passes through the intersection of the boundary line.

Optionally, in the step of providing the base substrate, the pixel unit area has a preset light-receiving area located at the intersection of the boundary lines and this area covers a portion of the four subunit areas located near the intersection; in the step of forming the light-splitting structure of the base substrate that penetrates the portion of the thickness of one side of the light-receiving surface, in each pixel unit area, the light-splitting structure is extended into the light-receiving area.

Optionally, in the step of providing the base substrate, in each pixel unit area, the intersection point of the boundary lines is the center point of the pixel unit area.

Optionally, in the step of forming the light-splitting structure that penetrates the portion of the thickness of the base substrate on one side of the light-receiving surface, the shape of the light-splitting structure is a long strip.

Optionally, in the step of forming the light-splitting structure that penetrates the portion of the thickness of the base substrate on one side of the light-receiving surface, the angle between the extending direction of the light-splitting structure and the row or column direction of the array arrangement is 30° to 60°.

Optionally, in the step of forming the light-splitting structure that penetrates a portion of the thickness of the base substrate on one side of the light-receiving surface, the angle between the extending direction of the light-splitting structure and the row or column direction of the array arrangement is 45°.

Optionally, the step of forming the light-shielding structure that passes through a portion of the thickness of the base substrate on one side of the light-receiving surface includes: patterning the base substrate to form a first groove in the base substrate located between adjacent pixel unit areas and between adjacent subunit areas; filling the first groove to form the light-shielding structure; the step of forming the light-splitting structure that passes through a portion of the thickness of the base substrate on one side of the light-receiving surface includes: patterning the base substrate to form a second groove in the base substrate distributed in each subunit area; filling the second groove to form the light-splitting structure.

Optionally, in the same step, the first groove and the second groove are filled.

### BRIEF DESCRIPTION OF THE DRAWINGS

The following drawings are merely examples for illustrative purposes according to various disclosed embodiments and are not intended to limit the scope of the present disclosure.

FIGS. 1 and 2 are schematic diagrams corresponding to a photoelectric sensor.

FIGS. 3-6 are structural schematics of an exemplary photoelectric sensor according to various embodiments of the present disclosure.

FIGS. 7-11 are schematic diagrams of structures of an exemplary photoelectric sensor at various stages during its fabrication according to various embodiments of the present disclosure.

### DETAILED DESCRIPTION

Reference will now be made in detail to exemplary embodiments of the invention, which are illustrated in the accompanying drawings. Wherever possible, the same reference numbers will be used throughout the drawings to refer to the same or like parts.

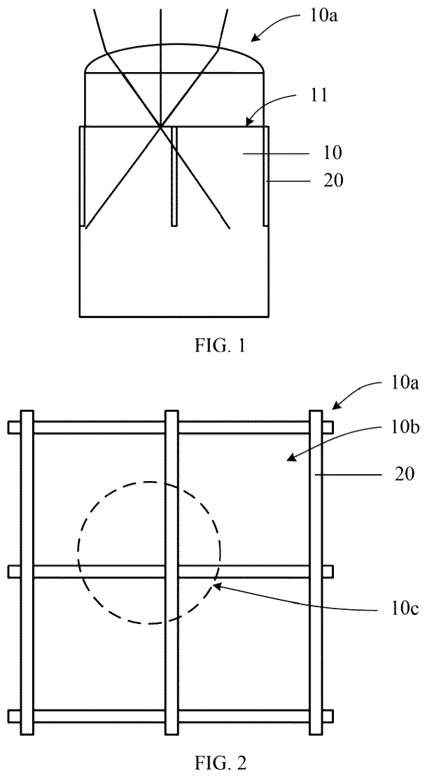

FIGS. 1 and 2 are schematic diagrams of structures corresponding to the photoelectric sensor.

With reference to FIGS. 1 and 2, a photoelectric sensor includes a base substrate 10. The base structure 10 has a light-receiving surface 11, and the base substrate 10 includes a photosensitive pixel area. The photosensitive pixel area includes a plurality of pixel unit areas 10a distributed in a matrix, and each pixel unit area 10a is divided into four subunit areas 10b arranged in an array. A light-shielding structure 20 penetrates a portion of the thickness of the base substrate 10 on a side of the light-receiving surface 11. The light-shielding structure 20 is located in the base substrate 10 between adjacent pixel unit areas 10a and between adjacent subunit areas 10b.

Each pixel unit area 10a is divided into four subunit areas 10b arranged in an array. When the pixel unit area 10a is exposed to light, the four subunit areas receive and sense the light at the same time, which is the quadrature phase detection (QPD) focusing. A lens is configured in each pixel unit area 10a. Each subunit area 10b under each lens corresponds to a photodiode. That is, a total of four photodiodes simultaneously sense the light and output electrical signals with phases. Subsequently, the four subunit areas 10b are combined in pairs to compare their phase differences with the reference value, thereby achieving the phase focusing. Correspondingly, the position of the light spot 10c caused by the focusing of lens is located at the center point of the pixel unit area 10a, e.g., the point where the four subunit areas 10b intersect. For each subunit area 10b, light is sensed within a certain angle range, causing the light sensitivity of each subunit area 10b is saturated at the sensed angle and with no light sensed in other areas of the same subunit area 10b. This may result in an excessively uneven light sensitivity within each subunit area 10b. Moreover, when the light spot 10c fluctuates in the working process, the amount of light entering the light spot 10c in each subunit area 10b will differ greatly. Thus, the uniformity of light sensing in the four subunit areas 10b is undesirable. Consequently, this leads to inaccurate focusing of the pixel unit areas 10a and poor focusing performance of the photoelectric sensor.

Embodiments of the present disclosure provide a photoelectric sensor. The photoelectric sensor includes a base substrate that has a light-receiving surface and a photosensitive pixel area. The photosensitive pixel area includes a plurality of pixel unit areas distributed in a matrix and each pixel unit area is divided into a plurality of subunit areas arranged in an array. The photoelectric sensor further includes a light-shielding structure that penetrates a portion of the thickness of the base substrate on a side of the light-receiving surface. The light-shielding structure is located in the base substrate between adjacent pixel unit areas and between adjacent subunit areas. The photoelectric sensor further includes a light-splitting structure that penetrates a portion of the thickness of the base substrate on a side of the light-receiving surface. The light-splitting structure is distributed in each subunit area in a one-to-one correspondence. An extending direction of each light-splitting structure has an acute angle with a row or column direction of the array of the subunit areas.

In various embodiments, each pixel unit area is divided into the plurality of subunit areas arranged in the array. The plurality of subunit areas simultaneously senses light when the pixel unit area is exposed to the light. They are subsequently aligned within the subunit areas to achieve focusing of the pixel unit area. When each pixel unit area is exposed to light and the light spot is more concentrated at the junction of the plurality of subunit areas, the light-splitting effect starts to work. As a result, the light can be better dispersed to the corresponding subunit areas. This disperse of light is beneficial to increase the effective photosensitive area of each subunit area and make the photosensitivity of each subunit area more uniform. Accordingly, it is also beneficial to reduce the non-uniformity of the photosensitivity between the plurality of subunit areas, enhance the accuracy of the focusing of the pixel unit area, and improve the focusing performance of the photoelectric sensor.

To further illustrate the above-mentioned purposes, features, and advantages of the embodiments of the present invention, the specific embodiments of the present invention are described in detail below with the associated drawings.

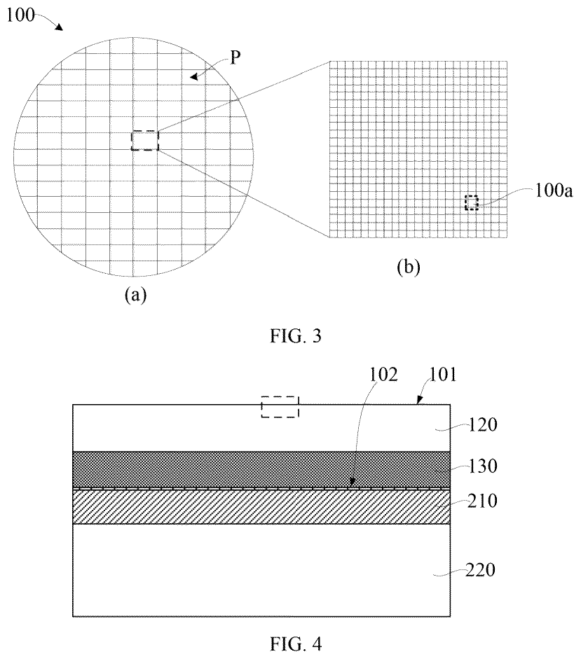

FIGS. 3-6 are schematic structural diagrams corresponding to the embodiment of the photoelectric sensor of the present invention.

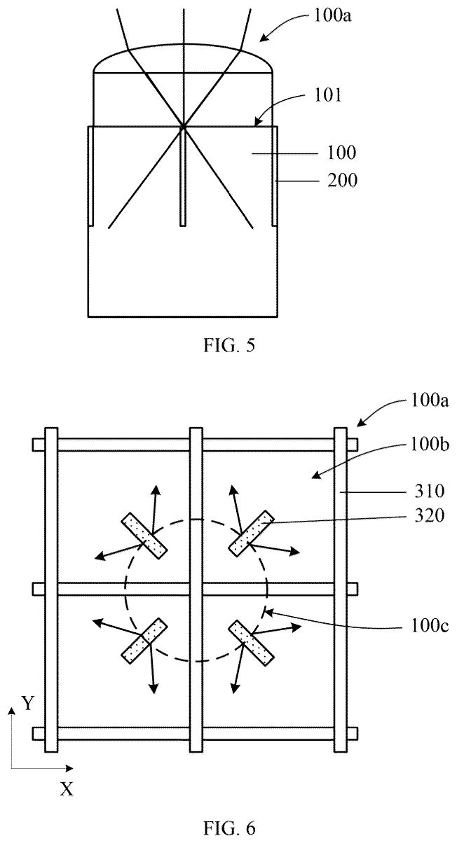

Referring to FIGS. 3-6, FIG. 3 (a) is a top view of the base substrate. FIG. 3 (b) is a partial enlarged view of any photosensitive pixel area in FIG. 3 (a). FIG. 4 is a cross-section view corresponding to FIG. 3 (a). FIG. 5 is a partial enlarged view of the dotted frame in FIG. 4. FIG. 6 is a top view of FIG. 5. The photoelectric sensor includes the following. A base substrate 100 having a light-receiving surface 101. The base substrate 100 includes a photosensitive pixel area P. The photosensitive pixel area P includes a plurality of pixel unit areas 100a distributed in the matrix. Each pixel unit area 100a is divided into a plurality of subunit areas 100b arranged in the array. A light-shielding structure 310 penetrates the portion of the thickness of the base substrate 100 on one side of the light-receiving surface 101. The light-shielding structure 310 is located between adjacent pixel unit area 100a and inside the base substrate 100. The base substrate 100 is between adjacent subunit areas 100b. The light-splitting structure 320 penetrates the base substrate 100 of the part of the thickness on one side of the light-receiving surface 101. The light-splitting structures 320 are distributed in each subunit area 100b one-to-one. The extending direction of each light-splitting structure 320 has an acute angle with the row direction (as shown in the X direction in FIG. 6) or the column direction (as shown in the Y direction in FIG. 6) of the array arrangement.

As an illustration of this embodiment, the photoelectric sensor is taken as a CIS as an example.

In other embodiments, the photoelectric sensor can also be a ToF sensor, a CCD image sensor, or an iToF (indirect ToF) sensor, etc.

The base substrate 100 is used to provide a process platform for subsequent process steps.

In this embodiment, the base substrate 100 includes a substrate 120 and a first interconnect structure layer 130 located on the substrate 120.

In this embodiment, the material of the substrate 120 includes silicon. The substrate 120 is a silicon substrate. In other embodiments, the material of the base substrate can also be other materials such as germanium, silicon germanium, silicon carbide, gallium arsenide, or indium gallium. The substrate can also be other types of substrates such as a silicon or germanium on an insulator.

In this embodiment, the base substrate 100 is a pixel wafer, including a first surface 102 where the first interconnection structure layer 130 is located, and a second surface opposite to the first surface 102.

In this embodiment, the base substrate 100 is a backside illumination (BSI) pixel wafer, which receives light from its second surface.

Correspondingly, in this embodiment, the photoelectric sensor is a BSI photoelectric sensor.

In other embodiments, the substrate can also be a frontside illumination (FSI) pixel wafer, receiving light from its first surface.

In this embodiment, only the photosensitive pixel area P and a part of the pixel unit area 100a are shown in the figure, and the pixel unit area 100a can also include a device structure such as a photoelectric substrate (for example, a photodiode). Among them, the photodiode can be a BSI single-photon avalanche diode (SPAD). For the purpose of simplification, the detailed structure of the above components is not shown in the embodiment of the present invention.

In this embodiment, the base substrate 100 is defined as a first base substrate 100, and the photoelectric sensor further includes: a second base substrate (not shown), which is used as a logic wafer and is bonded to the first surface 102 of the first base substrate 100.

The second base substrate is used as the logic wafer to analyze and process the electrical signals provided by the pixel wafer.

By placing the photosensitive pixel area P and a logic area on two wafers respectively and bonding the pixel wafer to the logic wafer, a larger pixel area can be obtained. Furthermore, this helps to shorten the path of light reaching the photoelectric device, reduce the scattering of light, and make the light more focused. In addition, the photosensitivity of the photoelectric sensor in a weak light environment is improved; the system noise and crosstalk are reduced.

In this embodiment, the substrate 120 of the first base substrate 100 is the first substrate 120. The second base substrate includes a second substrate 220 and a second interconnect structure layer 210 located on the substrate 220.

In this embodiment, the material of the second substrate 220 includes silicon. The second substrate 220 is a silicon substrate. In other embodiments, the material of the second substrate may also be other materials such as germanium, silicon germanium, silicon carbide, gallium arsenide, or indium gallium. The second substrate may also be other types of substrates such as a silicon substrate on an insulator or a germanium substrate on an insulator.

Accordingly, in this embodiment, a logic transistor (not shown) is also formed in the second base substrate. The logic transistor is used to perform logic processing on the electrical signal provided by the pixel wafer. Specifically, the logic transistor may include a logic gate structure located on the second base substrate, and a logic drain region and a logic source region located in the second base substrate on both sides of the logic gate structure.

As an embodiment, the bonding between the first base substrate 100 and the second base substrate is achieved by a hybrid bonding.

Specifically, in this embodiment, the pixel wafer and the logic wafer can be bonded together by using dielectric bonding. Then, an electrical connection between the first interconnect structure layer 130 and the second interconnect structure layer 210 is performed.

Among the aforementioned embodiment, the first interconnection structure layer 130 can be a first metal line. Alternatively, the first interconnection structure layer 130 is a first through silicon via (TSV) interconnection structure. Alternatively, the first interconnection structure layer 130 includes the first TSV interconnection structure and the first metal line located on the first TSV interconnection structure. A second interconnection structure layer 210 can be a second metal line. Alternatively, the second interconnection structure layer 210 is a second TSV interconnection structure. Alternatively, the second interconnection structure layer 210 includes the second TSV interconnection structure and the second metal line located on the second TSV interconnection structure.

It should be noted that the aforementioned bonding method between the first base substrate 100 and the second base substrate is only an embodiment. The bonding method between the first base substrate 100 and the second base substrate is not limited to this. For instance, in other embodiments, the bonding method between the first base substrate and the second base substrate can also be a direct bonding (such as a melt bonding and an anodic bonding) or an indirect bonding technology (such as a metal eutectic, a hot pressing bonding, and an adhesive bonding).

In this embodiment, the base substrate 100 has the light-receiving surface 101. The light-receiving surface 101 refers to the surface for receiving light.

The photosensitive pixel area P is used to receive optical signals. Thus, the optical signals are converted into electrical signals.

In the base substrate 100, there are the plurality of photosensitive pixel areas P. The plurality of photosensitive pixel areas P is arranged in a matrix. The pixel unit area 100a is used to form a pixel. The subunit areas 100b of each pixel unit area 100a are used to receive light signals at the same time.

In this embodiment, each pixel unit area 100a has four subunit areas 100b arranged in an array.

In this embodiment, each pixel unit area 100a is divided into the plurality of subunit areas 100b arranged in an array. When the pixel unit area 100a is exposed to light, the four subunit areas 100b are exposed to light and sense the light at the same time when the pixel unit area 100a is exposed to light. That is, QPD focusing. Each pixel unit area 100a has a lens. Each subunit area 100b under each lens corresponds to a photodiode. That is, a total of four photodiodes sense light at the same time and output electrical signals with phases. Subsequently, the four subunit areas 100b are combined in pairs. Their phase differences are compared with the reference value. Hence, phase focusing is achieved.

The light-shielding structure 310 is used to prevent optical crosstalk between adjacent pixels and to divide adjacent subunit areas 100b.

Specifically, the light-shielding structure 310 has a shielding effect on light. The light-shielding structure 310 is located between the light-transmitting layers of adjacent pixel unit areas 100a. When incident light irradiates the photosensitive pixel region P, the incident light can only enter the corresponding pixel unit area 100a through the light-transmitting layer. The incident light can neither pass through the light-shielding structure 310 around the light-transmitting layer nor enter other adjacent pixel unit areas 100a. Thus, the optical crosstalk to other pixel unit areas 100a is avoided.

In this embodiment, the material of the light-shielding structure 310 is a conductive material. The conductive material is usually opaque. Hence, the light-shielding structure 310 can be used to shield light.

As an example, the conductive material can be a metal material. Specifically, the material of the light-shielding structure 310 includes one or more of W, Al, Cu, Ti, TiN, Ta, and TaN. In this embodiment, the material of the light-shielding structure 310 is W.

In other embodiments, the conductive material can also be polysilicon doped with conductive ions.

In this embodiment, the light-shielding structures 310 between the four subunit areas 100b intersect vertically.

Correspondingly, the light-shielding structure 310 divides the pixel unit area 100a into four subunit areas 100b in a [symbol] -shaped array.

In this embodiment, the pixel unit area 100a has a predetermined light-receiving area 100c. This area 100c is located at the intersection of the light-shielding structure 310 therein and covers a partial area of the four subunit areas 100b near their intersection.

The preset light-receiving area 100c is the area where light converges on the pixel unit area 100a of the light-receiving surface 101 when the preset light is received.

In this embodiment, in each pixel unit area 100a, the intersection of the light-shielding structure 310 therein is the center point of the pixel unit area 100a.

The intersection of the light-shielding structure 310 inside is the center point of the pixel unit area 100a. Thus, the subunit areas 100b divided by the light-shielding structure 310 are evenly arranged. The photosensitive areas of each subunit area 100b are similar. This similarity makes the photosensitivity of each subunit area 100b more uniform and the focus of the pixel unit area 100a more precise.

The light-splitting structure 320 is used to split the light incident on the subunit area 100b. Specifically, the extending direction of each light-splitting structure 320 has an acute angle with the row or column direction of the array arrangement. When the light is incident on the subunit area 100b, it is reflected by the light-splitting structure 320 and dispersed into the corresponding subunit area 100b.

In this embodiment, each pixel unit area 100a is divided into the plurality of subunit areas 100b arranged in the array. When the pixel unit area 100a is exposed to light, the plurality of subunit areas 100b senses light and are simultaneously received light. The plurality of subunit areas 100b is subsequently aligned with the subsequent subunit areas in 100b to achieve focusing of the pixel unit area 100a. When each pixel unit area 100a is exposed to light and the light spot is more concentrated at the junction of the plurality of subunit areas 100b, a light-splitting effect starts to work. Thus, the light can be better dispersed to the corresponding subunit area 100b. This dispersion of light is beneficial to increase the effective light-sensitive area of each subunit area 100b, enhance the uniformity of the light-sensitive of each subunit area 100b. In addition, this light dispersion is beneficial to reduce the light-sensitive area of the plurality of subunit areas 100b and improve the accuracy of the focus of the pixel unit area 100a. Hence, the focus performance of the photoelectric sensor is improved.

In this embodiment, the extension of the light-shielding structure 310 divides the pixel unit area 100a. Accordingly, in this embodiment, the extending direction of each light-splitting structure 320 has an acute angle with the extending direction of the light-shielding structure 310 inside the pixel unit area 100a.

In this embodiment, inside each pixel unit area 100a, the extending direction of the light-splitting structure 320 passes through the intersection of the light-shielding structure 310. The light-shielding structure 310 is inside the pixel unit area 100a.

The extending direction of the light-splitting structure 320 passes through the intersection of the light-shielding structure 310 inside the pixel unit area 100a. The light-splitting structure 320 in each subunit area 100b points to the center of the preset light-receiving area 100c. Thus, in each subunit area 100b, the light-splitting effect of the light-splitting structure 320 on the light incident to the preset light-receiving area 100c is more uniform.

In this embodiment, in each pixel unit area 100a, the light-splitting structure 320 extends into the light-receiving area 100c.

In each pixel unit area 100a, the light-splitting structure 320 extends into the light-receiving area 100c. Hence, the incident light in each subunit area 100b can be split.

In this embodiment, the shape of the light-splitting structure 320 is a long strip.

The shape of the light-splitting structure 320 is a long strip. Thus, the light-splitting structure 320 can split as much incident light as possible while occupying as little space as possible.

It should be noted that in this embodiment, the length of the light-splitting structure 320 should be neither excessively large nor small. If the length of the light-splitting structure 320 is excessively large, it is easy to cause unnecessary waste and increase the difficulty of forming the light-splitting structure 320. If the length of the light-splitting structure 320 is excessively small, it is easy to cause the following disadvantages. Areas, where the incident light can be split, is too few. The light-splitting effect of the light-splitting structure 320 on the incident light is insufficient; the insufficiency would affect the light-splitting effect of the light-splitting structure 320 and increase the difficulty in achieving uniformity of the photosensitivity for each subunit area 100b. For this reason, in this embodiment, the length of the light-splitting structure 320 is 200 nm to 600 nm.

It should also be noted that, in this embodiment, the width of the light-splitting structure 320 should neither be excessively large nor small. If the width of the light-splitting structure 320 is excessively large, it is easy to occupy too much space of the subunit area 100b and cause unnecessary waste. If the width of the light-splitting structure 320 is excessively small, it is easy to cause difficulties in forming the light-splitting structure 320. For this reason, in this embodiment, the width of the light-splitting structure 320 is 100 nm to 300 nm.

It should also be noted that in this embodiment, the angle between the extending direction of the light-splitting structure 320 and the row or column direction of the array arrangement should neither be excessively large nor small. If the angle between the extending direction of the light-splitting structure 320 and the row or column direction of the array arrangement is excessively large or small, it is easy to cause the extending direction of the light-splitting structure 320 to be too close to the row or column direction. This too close in the extending direction will cause the incident light to be too concentrated, increase the difficulty in achieving a better light-splitting effect, and increase the difficulty in achieving a more uniform light sensitivity effect for each subunit area 100b. For this reason, in this embodiment, the angle between the extending direction of the light-splitting structure 320 and the row or column direction of the array arrangement is 30° to 60°.

Specifically, in this embodiment, the angle between the extending direction of the light-splitting structure 320 and the row or column direction of the array arrangement is 45°. This angle is beneficial for further achieving better dispersion of the incident light to the corresponding subunit area 100b, increasing the effective photosensitivity area of each subunit area 100b, and making the photosensitivity of each subunit area 100b more uniform.

In this embodiment, when forming the light-shielding structure 310, the material is filled to form the light-splitting structure 320. Therefore, in this embodiment, the material of the light-splitting structure 320 is the same as that of the light-shielding structure 310.

Accordingly, in this embodiment, the material of the light-splitting structure 320 is a conductive material. Conductive materials are usually opaque. Thus, the light-splitting structure 320 can work as the light-splitting device.

For instance, the conductive material can be a metal material. Specifically, the material of the light-splitting structure 320 includes one or more of W, Al, Cu, Ti, TiN, Ta, and TaN. In this embodiment, the material of the light-splitting structure 320 is W.

In other embodiments, the conductive material can also be polysilicon doped with conductive ions.

In this embodiment, the photoelectric sensor further includes: a light-transmitting layer covering the light-receiving surface 101 of each subunit area 100b in the base substrate 100.

The light-transmitting layer has a light-transmitting property. When the light-transmitting layer is formed on the light-receiving surface 101, light can pass through the light-transmitting layer and illuminate the light-receiving surface 101.

In this embodiment, the material of the light-transmitting layer is a light-transmitting material. The material of the light-transmitting layer is an insulating material. The insulating material prevents the electrical properties of the photoelectric sensor from being affected. In this embodiment, the material of the light-transmitting layer includes silicon oxide, silicon nitride, silicon oxynitride or silicon carbide. As an example, the material of the light-transmitting layer is silicon oxide. Silicon oxide has high process compatibility, low cost, good light transmission, and insulation properties.

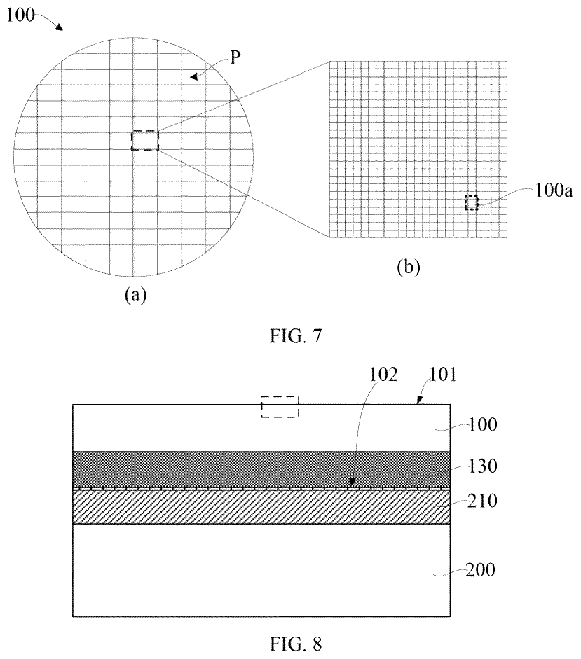

FIGS. 7-11 are schematic diagrams of structures corresponding to each step in the embodiment of the method for forming the photoelectric sensor of the present invention.

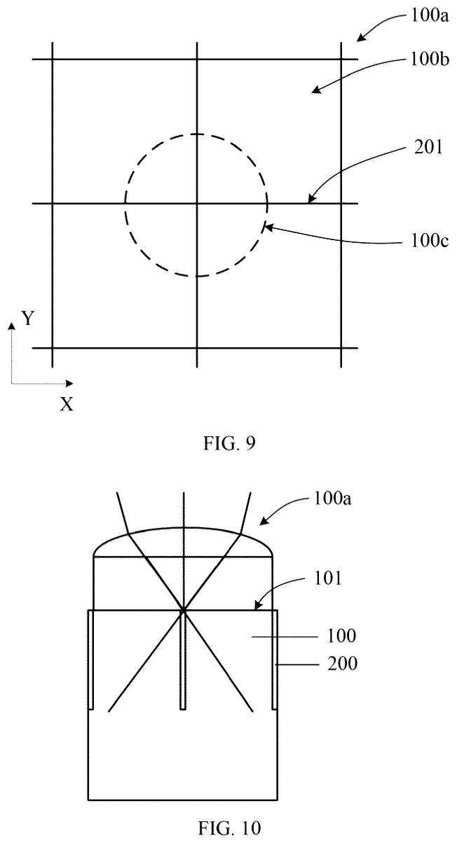

Referring to FIGS. 7-9, FIG. 7 (a) is a top view of the base substrate. FIG. 7 (b) is a partial enlarged view of any photosensitive pixel area in FIG. 7 (a). FIG. 8 is a cross-sectional view corresponding to FIG. 7 (a). FIG. 9 is a top view of FIG. 8. The base substrate 100 is provided and the base substrate 100 has the light-receiving surface 101. The base substrate 100 includes a photosensitive pixel area P. The photosensitive pixel area P includes the plurality of pixel unit areas 100a distributed as a matrix. Each pixel unit area 100a is divided into the plurality of subunit areas 100b arranged in the array.

As an example, in this embodiment, the photoelectric sensor is taken as the CIS for illustration.

In other embodiments, the photoelectric sensor can also be a ToF sensor, a CCD image sensor, or an iToF sensor.

The base substrate 100 is used to provide a process platform for subsequent process steps.

In this embodiment, the base substrate 100 includes the substrate 120 and the first interconnection structure layer 130 located on the substrate 120.

In this embodiment, the material of the substrate 120 includes silicon. The substrate 120 is a silicon base substrate. In other embodiments, the material of the substrate can also be other materials such as germanium, silicon germanium, silicon carbide, gallium arsenide, or indium gallium. The substrate can also be other types of base substrates such as a silicon base substrate on an insulator or a germanium base substrate on an insulator.

In this embodiment, the base substrate 100 is the pixel wafer. It includes the first surface 102 where the first interconnect structure layer 130 is located and a second surface opposite to the first surface 102.

In this embodiment, the base substrate 100 is the BSI pixel wafer. The BSI pixel wafer receives light from its second surface.

Accordingly, in this embodiment, the photoelectric sensor is the BSI photoelectric sensor.

In other embodiments, the base substrate may also be an FSI pixel wafer, which receives light from its first surface.

In this embodiment, only the photosensitive pixel region P and a portion of the pixel unit area 100a are shown in the figure. The pixel unit area 100a may also include a device structure such as a photoelectric substrate (e.g., a photodiode). Among them, the photodiode may be the BSI SPAD. For the purpose of simplicity, the detailed structure of the above components is not shown in the embodiment of the present invention.

In this embodiment, the base substrate 100 is defined as the first base substrate 100. The photoelectric sensor further includes: a second base substrate (not shown). The second base substrate is used as the logic wafer and is bonded to the first surface 102 of the first base substrate 100.

The second base substrate is used as the logic wafer to analyze and process the electrical signal provided by the pixel wafer.

By setting the photosensitive pixel area P and the logic area on two wafers respectively, and bonding the pixel wafer with the logic wafer together, a larger pixel area can be obtained. Then, the path of light reaching the photoelectric substrate is shorten; the scattering of light is reduced; the light is more focused; the photosensitivity of the photoelectric sensor in a weak light environment is improved; the system noise and crosstalk are reduced.

In this embodiment, the substrate 120 of the first base substrate 100 is the first substrate 120. The second base substrate includes the second substrate 220 and the second interconnect structure layer 210 located on the second substrate 220.

In this embodiment, the material of the second substrate 220 includes silicon. The second substrate 220 is a silicon substrate. In other embodiments, the material of the second base substrate can also be other materials such as germanium, silicon germanium, silicon carbide, gallium arsenide, or indium gallium. The second base substrate can also be other types of base substrates such as the silicon base substrate on the insulator or the germanium base substrate on the insulator.

Accordingly, in this embodiment, the logic transistor (not shown) is also formed in the second base substrate. The logic transistor is used to perform logic processing on the electrical signal provided by the pixel wafer. Specifically, the logic transistor can include the logic gate structure located on the second base substrate. The logic drain region and the logic source region located in the second base substrate on both sides of the logic gate structure.

As an embodiment, the bonding between the first base substrate 100 and the second base substrate is achieved by hybrid bonding.

Specifically, in this embodiment, the pixel wafer and the logic wafer can be bonded together by using dielectric bonding. Then, the first interconnect structure layer 130 and the second interconnect structure layer 210 can be electrically connected.

The first interconnect structure layer 130 can be the first metal line. Alternatively, the first interconnect structure layer 130 can be the first TSV interconnect structure. Alternatively, the first interconnect structure layer 130 can include the first TSV interconnect structure and the first metal line located on the first TSV interconnect structure. The second interconnect structure layer 210 can be the second metal line. Alternatively, the second interconnect structure layer 210 can be the second TSV interconnect structure. Alternatively, the second interconnect structure layer 210 may include the second TSV interconnect structure and the second metal line located on the second through hole interconnect structure.

It should be noted that the aforementioned method for achieving bonding between the first base substrate 100 and the second base substrate is only an embodiment. The bonding method between the first base substrate 100 and the second base substrate is not limited to the above approach. For instance, in other embodiments, the bonding method of the first and the second base substrate can also be direct bonding (e.g., melt bonding and anodic bonding) or indirect bonding technology (e.g., metal eutectic, hot pressing bonding, and adhesive bonding).

In this embodiment, the base substrate 100 has the light-receiving surface 101. Among them, the light-receiving surface 101 refers to the surface for receiving light.

The photosensitive pixel area P is used to receive optical signals. Consequently, the optical signals are converted into electrical signals.

In the base substrate 100, there are the plurality of photosensitive pixel areas P. The plurality of photosensitive pixel areas P is arranged in the matrix. The pixel unit area 100a is used to form the pixel. The subunit area 100b of each pixel unit area 100a is used to receive light signals simultaneously.

In this embodiment, in the step of providing the base substrate 100, each pixel unit area 100a has four subunit areas 100b arranged in the array. Boundary lines 201 between the four subunits 100b intersect vertically.

In this embodiment, each pixel unit area 100a is divided into the plurality of subunit areas 100b arranged in the array. When the pixel unit area 100a is exposed to light, the four subunit areas 100b are exposed to light and sense light simultaneously. That is, QPD focusing. Each pixel unit area 100a has a lens. Each subunit area 100b under each lens corresponds to a photodiode. That is, a total of four photodiodes sense light simultaneously. Electrical signals with phases are then generated as output. The four subsequent subunit areas 100b are combined in pairs. Their phase differences are compared with the reference value. Thus, the phase focusing is achieved.

Correspondingly, boundary lines 201 divide the pixel unit area 100a into four subunit areas 100b in a [symbol] -shaped array.

In this embodiment, in the step of providing the base substrate 100, the pixel unit area 100a has a preset light-receiving area 100c located at the intersection of boundary lines 201. The light-receiving area 100c covers a portion of the area of four subunit areas 100b located near the intersection.

The preset light-receiving area 100c is a region where light is concentrated on the pixel unit area 100a of the light-receiving surface 101, when the preset light is received.

In this embodiment, in the step of providing the base substrate 100, in each pixel unit area 100a, the intersection of boundary lines 201 is the center point of the pixel unit area 100a.

The intersection of boundary lines 201 is the center point of the pixel unit area 100a. Thus, the subunit areas 100b divided by boundary lines 201 are evenly arranged. Photosensitive areas of each subunit area 100b are similar. Hence, the photosensitivity of each subunit area 100b is more uniform. In the meanwhile, the focus of the pixel unit area 100a is more accurate.

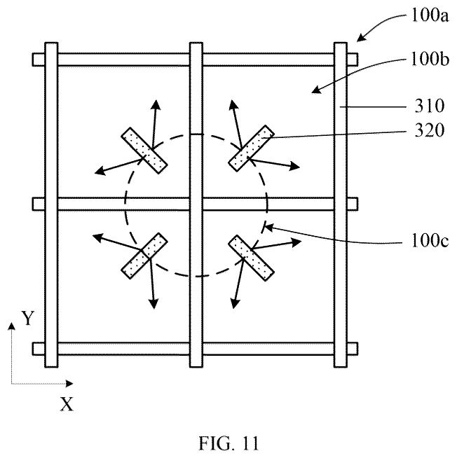

Referring to FIGS. 10 and 11, FIG. 10 is a partial enlarged view of the dotted box in FIG. 8. FIG. 11 is a top view corresponding to FIG. 9. FIG. 11 forms the light-shielding structure 310 that penetrates the portion of the thickness of the base substrate 100 on one side of the light-receiving surface 101. The light-shielding structure 310 is located in the base substrate 100 between adjacent pixel unit areas 100a and between adjacent subunit areas 100b. FIG. 11 also forms the light-splitting structure 320 that penetrates the portion of the thickness of the base substrate 100 on one side of the light-receiving surface 101. The light-splitting structures 320 are distributed one-to-one in each subunit area 100b. The extending direction of each light-splitting structure 320 has an acute angle with the row direction (as shown in the X direction in FIG. 11) or the column direction (as shown in the Y direction in FIG. 11) of the array arrangement.

Accordingly, in this embodiment, the light-shielding structure 310 is formed at the position of the boundary line 301 to divide the pixel unit area 100a into the plurality of subunit areas 100b.

The light-shielding structure 310 is used to prevent optical crosstalk between adjacent pixels. The light-shielding structure 310 is also used to divide adjacent subunit areas 100b.

Specifically, the light-shielding structure 310 has a shielding effect on light. The light-shielding structure 310 is located between the light-transmitting layers of adjacent pixel unit areas 100a. When the incident light irradiates the photosensitive pixel area P, the incident light will only enter the corresponding pixel unit area 100a through the light-transmitting layer. The incident light cannot pass through the light-shielding structure 310 around the light-transmitting layer to enter other adjacent pixel unit areas 100a. Thus, the optical crosstalk to other pixel unit areas 100a is avoided.

In this embodiment, the material of the light-shielding structure 310 is a conductive material. Conductive materials are usually opaque. Hence, the light-shielding structure 310 can be used to shield light.

As an example, the conductive material can be a metal material. Specifically, the material of the light-shielding structure 310 includes one or more of W, Al, Cu, Ti, TiN, Ta, and TaN. In this embodiment, the material of the light-shielding structure 310 is W.

In other embodiments, the conductive material can also be polysilicon doped with conductive ions.

The light-splitting structure 320 is used to split the light incident on the subunit area 100b. Specifically, the extending direction of each light-splitting structure 320 has an acute angle with the row or column direction of the array arrangement. When the light is incident on the subunit area, it is reflected by the light-splitting structure 320 and dispersed into the corresponding subunit area 100b.

In this embodiment, each pixel unit area 100a is divided into the plurality of subunit areas 100b arranged in the array. When the pixel unit area 100a is exposed to light, the plurality of subunit areas 100b is simultaneously exposed to light and sense light. The plurality of subunit areas 100b is subsequently aligned to achieve the focusing of the pixel unit area 100a. When each pixel unit area 100a is exposed to light and the light spot is more concentrated at the junction of the plurality of subunit areas 100b, the splitting-light effects start to work. Hence, the light can be better dispersed to the corresponding subunit area 100b. Furthermore, the light-sensitive area of each subunit area 100b can be increased. Thus, the light-sensitive of each subunit area 100b is more uniform. Accordingly, the photosensitivity non-uniformity between the plurality of subunit areas 100b can be reduced. The focusing of the pixel unit area 100a is more accurate. The focusing performance of the photoelectric sensor can be improved.

In this embodiment, the extension of boundary lines 201 divide the pixel unit area 100a. Accordingly, in this embodiment, in the step of forming the light-splitting structure 320, the partial thickness of the base substrate 100 on one side of the light-receiving surface 101 is penetrated. The extending direction of each light-splitting structure 320 has an acute angle with the extending direction of boundary lines 201.

In this embodiment, in the step of forming the light-splitting structure 320, the portion of the thickness of the base substrate 100 on one side of the light-receiving surface 101 is penetrated. In each pixel unit area 100a, the extending direction of the light-splitting structure 320 passes through the intersection of boundary lines 201.

The extending direction of the light-splitting structure 320 passes through the intersection of boundary lines 201. The light-splitting structure 320 in each subunit area 100b points to the center of the preset light receiving area 100c. Thus, in each unit area 100b, the light-splitting effect of the light-splitting structure 320 on the light incident to the preset light-receiving area 100c is more uniform.

In this embodiment, in the step of forming the light-splitting structure 320, the portion of the thickness of the substrate 100 on one side of the light-receiving surface 101 is penetrated. In each pixel unit area 100a, the light-splitting structure 320 extends to the light-receiving area 100c.

In each pixel unit area 100a, the light-splitting structure 320 extends to the light-receiving area 100c. Thus, the incident light in each subunit area 100b can be split.

In this embodiment, in the step of forming the light-splitting structure 320 of the base substrate 100, the partial thickness of the light-receiving surface 101 is penetrated. The shape of the light-splitting structure 320 used in this step, is the long strip.

The shape of the light-splitting structure 320 is the long strip. Hence, the light-splitting structure 320 can split as much incident light as possible. In the meanwhile, the light-splitting structure 320 occupies as little space as possible.

In the present embodiment, in the step of forming the light-splitting structure 320 of the base substrate 100, the partial thickness on one side of the light-receiving surface 101 is penetrated. It should be noted that, the length of the light-splitting structure 320 needs to be neither excessively large nor small. If the length of the light-splitting structure 320 is excessively large, it can cause unnecessary waste and difficulty in forming the light-splitting structure 320. If the length of the light-splitting structure 320 is excessively small, it can cause too few areas where the incident light can be split, and the light-splitting effect of the light-splitting structure 320 on the incident light is insufficient. Consequently, the light-splitting effect of the light-splitting structure 320 is affected. Then, it is difficult to achieve the effect of making the photosensitivity of each subunit area 100b more uniform. For this reason, in the step of forming the light-splitting structure 320 of the base substrate 100 that penetrates the partial thickness on one side of the light-receiving surface 101 in the present embodiment, the length of the light-splitting structure 320 is 200 nm to 600 nm.

In the step of forming the light-splitting structure 320 of the base substrate 100, the partial thickness on one side of the light-receiving surface 101 in this embodiment is penetrated. It should be noted that, the width of the light-splitting structure 320 should be neither excessively large nor small. If the width of the light-splitting structure 320 is excessively large, it can occupy too much space of the subunit area 100b, and cause unnecessary waste. If the width of the light-splitting structure 320 is excessively small, it can cause difficulties in forming the light-splitting structure 320. For this reason, in the step of forming the light-splitting structure 320 of the base substrate 100 that penetrates the partial thickness on one side of the light-receiving surface 101 in this embodiment, the width of the light-splitting structure 320 is 100 nm to 300 nm.

In the step of forming the light-splitting structure 320 of the base substrate 100, the partial thickness of one side of the light-receiving surface 101 is penetrated in the present embodiment. It should be noted that the angle between the extending direction of the light-splitting structure 320 and the row or column direction of the array arrangement should neither be excessively large or small. If the angle between the extending direction of the light-splitting structure 320 and the row or column direction of the array arrangement is excessively large or small, it can cause the extending direction of the light-splitting structure 320 to be too close to the row or column direction. Thus, it will cause the incident light to be too concentrated. Achieving a better light-splitting effect also becomes difficult. Likewise, achieving the effect of making the photosensitivity of each subunit area 100b more uniform becomes difficult. For this reason, in the present embodiment, in the step of forming the light-splitting structure 320 of the base substrate 100 that penetrates the partial thickness of one side of the light-receiving surface 101, the angle between the extending direction of the light-splitting structure 320 and the row or column direction of the array arrangement is 30° to 60°.

In the present embodiment, in the step of forming the light-splitting structure 320, the portion of the thickness of the base substrate 100 on one side of the light-receiving surface 101 is penetrated. Specifically, the angle between the extending direction of the light-splitting structure 320 and the row or column direction of the array arrangement is 45°. This is beneficial for further achieving better dispersion of the incident light to the corresponding subunit area 100b. This is also beneficial for increasing the effective photosensitivity area of each subunit area 100b. In addition, this is beneficial for making the photosensitivity of each subunit area 100b more uniform.

In this embodiment, the step of forming the light-shielding structure 310 of the base substrate 100, the portion of the thickness of the light-receiving surface 101 is penetrated. This step includes: patterning the base substrate 100 to form a first groove in the base substrate 100 between adjacent pixel unit areas 100a and between adjacent subunit areas 100b.

The first groove is used to form the light-shielding structure 310.

In this embodiment, the first groove is filled to form the light-shielding structure 310.

In this embodiment, the step of forming the light-splitting structure 320 of the base substrate 100, the portion of the thickness of the light-receiving surface 101 is penetrated.

This step includes: patterning the base substrate 100 to form a second groove in the base substrate 100 distributed in each subunit area 100b.

The second groove is used to form the light-splitting structure 320.

In this embodiment, the second groove is filled to form the light-splitting structure 320.

In this embodiment, the first and the second grooves are filled in the same step. Thus, in this embodiment, the material of the light-splitting structure 320 is the same as that of the light-shielding structure 310.

Accordingly, in this embodiment, the material of the-light-splitting structure 320 is a conductive material. Conductive materials are typically opaque. Hence, the light-splitting structure 320 can play the role of splitting light.

As an example, the conductive material can be a metal material. Specifically, the material of the light-splitting structure 320 includes one or more of W, Al, Cu, Ti, TiN, Ta, and TaN. In this embodiment, the material of the light-splitting structure 320 is W.

In other embodiments, the conductive material can also be polysilicon doped with conductive ions.

In this embodiment, the method for forming the photoelectric sensor further includes: forming the light-transmitting layer. The layer covers the light-receiving surface 101 of the base substrate 100 of each subunit area 100b.

The light-transmitting layer has a light-transmitting property. When the light-transmitting layer is formed on the light-receiving surface 101, light can pass through the light-transmitting layer. The light can further irradiate on the light-receiving surface 101.

In this embodiment, the material of the light-transmitting layer is the light-transmitting material. The material of the light-transmitting layer is the insulating material to prevent the electrical properties of the photoelectric sensor from being affected. In this embodiment, the material of the light-transmitting layer includes silicon oxide, silicon nitride, silicon oxynitride, or silicon carbide. As an example, the material of the light-transmitting layer is silicon oxide. Silicon oxide has high process compatibility and low cost. Additionally, silicon oxide has good light transmission and insulation properties.

Compared with current techniques, the technical scheme of the embodiment of the present invention has several advantages.

In the photoelectric sensor provided by the embodiment of the present invention, the splitting-structures are distributed one by one in each subunit area, and the extending direction of each splitting-structure has an acute angle with the row or column direction of the array arrangement. In the embodiment of the present invention, each pixel unit area is divided into multiple subunit areas arranged in an array, and multiple subunit areas are simultaneously photosensitive when the pixel unit area is exposed to light; the subsequent subunit areas are aligned to achieve the focusing of the pixel unit area. As a result, the light can be better dispersed to the corresponding subunit areas. This disperse of light is beneficial for increasing the effective photosensitive area of each subunit area and enhancing the uniformity of photosensitivity of each subunit areas. Accordingly, this disperse of light is beneficial to reduce the unevenness of photosensitivity between multiple subunit areas, to make the focus of the pixel unit area more accurate, and then to improve the focusing performance of the photoelectric sensor.

In the method for forming the photoelectric sensor provided in the embodiment of the present invention, the light-splitting structure is formed that penetrates the portion of the thickness of a base substrate on one side of the light-receiving surface, and the light-splitting structures are distributed one by one in each subunit area, and the extending direction of each light-splitting structure has an acute angle with the row or column direction of the array arrangement. In the embodiment of the present invention, each pixel unit area is divided into multiple subunit areas arranged in an array, and multiple subunit areas are simultaneously photosensitive when the pixel unit area is exposed to light; the subsequent subunit areas are aligned to achieve the focusing of the pixel unit area. As a result, the light can be better dispersed to the corresponding subunit areas. This disperse of light is beneficial for increasing the effective photosensitive area of each subunit area and enhancing the uniformity of photosensitivity of each subunit areas. Accordingly, this disperse of light is beneficial to reduce the unevenness of photosensitivity between multiple subunit areas, to make the focus of the pixel unit area more accurate, and then to improve the focusing performance of the photoelectric sensor.

The embodiments disclosed herein are exemplary only. Other applications, advantages, alternations, modifications, or equivalents to the disclosed embodiments are obvious to those skilled in the art and are intended to be encompassed within the scope of the present disclosure.

What is claimed is:

1. A photoelectric sensor, comprising:
a base substrate having a light-receiving surface, wherein the base substrate includes a photosensitive pixel area, the photosensitive pixel area includes a plurality of pixel unit areas distributed in a matrix, and each pixel unit area of the plurality of pixel unit areas is divided into a plurality of subunit areas in an array arrangement;
a plurality of light-shielding structures, penetrating a portion of a thickness of the base substrate on a side of the light-receiving surface, and located in the base substrate between adjacent pixel unit areas of the plurality of pixel unit areas and between adjacent subunit areas of the plurality of subunit areas; and
a plurality of light-splitting structures, penetrating a portion of the thickness of the base substrate on the side of the light-receiving surface, and distributed in the plurality of subunit areas in a one-to-one correspondence, wherein an extending direction of each light-splitting structure of the plurality of light-splitting structures has an acute angle with a row or column direction of the array arrangement.

2. The photoelectric sensor according to claim 1, wherein each pixel unit area of the plurality of pixel unit areas has four subunit areas arranged in an array, and the plurality of light-shielding structures between the four subunit areas intersect vertically; and
the extending direction of each light-splitting structure has an acute angle with an extending direction of the light-shielding structure that is inside the pixel unit area.

3. The photoelectric sensor according to claim 2, wherein in each pixel unit area, the extending direction of the light-splitting structure passes through an intersection of the light-shielding structures that is inside the pixel unit area.

4. The photoelectric sensor according to claim 2, wherein the pixel unit area includes a preset light-receiving area that is at an intersection of the light-shielding structures located therein, and covers a partial area of the four subunit areas located near the intersection; and
in each of the pixel unit areas, the light-splitting structure extends into the light-receiving area.

5. The photoelectric sensor according to claim 4, wherein in each of the pixel unit areas, the intersection of the light-shielding structures inside the pixel unit area is a center point of the pixel unit area.

6. The photoelectric sensor according to claim 1, wherein a shape of the light-splitting structure includes a long strip.

7. The photoelectric sensor according to claim 6, wherein a length of the light-splitting structure is 200 nm to 600 nm; and a width of the light-splitting structure is 100 nm to 300 nm.

8. The photoelectric sensor according to claim 1, wherein the angle between the extending direction of the light-splitting structure and the row or column direction of the array arrangement is 30° to 60°.

9. The photoelectric sensor according to claim 8, wherein the angle between the extending direction of the light-splitting structure and the row or column direction of the array arrangement is 45°.

10. The photoelectric sensor according to claim 1, wherein the light-splitting structure and the light-shielding structure are made of a same material.

11. A method for forming a photoelectric sensor, comprising:
providing a base substrate, the base substrate having a light-receiving surface, and the base substrate including a photosensitive pixel area, the photosensitive pixel area including a plurality of pixel unit areas distributed in a matrix, and each of the pixel unit area being divided into a plurality of subunit areas in an array;
forming plurality of light-shielding structures that penetrates a portion of a thickness of the base substrate on a side of the light-receiving surface, and that is located in the base substrate between adjacent pixel unit areas of the plurality of pixel unit areas and between adjacent subunit areas of the plurality of subunit areas; and
forming a plurality of light-splitting structures that penetrates a portion of the thickness of the base substrate on the side of the light-receiving surface and that is distributed in the plurality of subunit areas in a one-to-one correspondence, wherein an extending direction of each light-splitting structure of the plurality of the light-splitting structures has an acute angle with a row or column direction of the array arrangement.

12. The method according to claim 11, wherein
forming the plurality of light-shielding structures comprises:
patterning the base substrate to form a plurality of first grooves in the base substrate between the adjacent pixel unit areas and between the adjacent subunit areas, and
forming the plurality of light-shielding structures by filling the plurality of first grooves; and
forming the plurality of light-splitting structures comprises:
patterning the base substrate to form a plurality of second grooves distributed in the base substrate of each subunit area, and
forming the plurality of light-splitting structures by filling the plurality of second grooves.

13. The method according to claim 12, wherein the plurality of first grooves and the plurality of second grooves are filled in a same, single process.

14. The method according to claim 11, wherein the base substrate is provided with each pixel unit area of the plurality of pixel unit areas having four subunit areas arranged in an array, and boundary lines between the four subunit areas intersect vertically; and
when forming the plurality of light-splitting structures, the extending direction of each light-splitting structure has an acute angle with an extending direction of a boundary line.

15. The method according to claim 14, wherein in each pixel unit area, the extending direction of the light-splitting structure passes through an intersection of the boundary lines.

16. The method according to claim 14, wherein the pixel unit area includes a preset light-receiving area that is at an intersection of the light-shielding structures located therein, and covers a partial area of the four subunit areas located near the intersection; and in each of the pixel unit areas, the light-splitting structure extends into the light-receiving area.

17. The method according to claim 16, wherein in each of the pixel unit areas, the intersection of the light-shielding structures inside the pixel unit area is a center point of the pixel unit area.

18. The method according to claim 11, wherein a shape of the light-splitting structure is a long strip.

19. The method according to claim 11, wherein the angle between the extending direction of the light-splitting structure and the row or column direction of the array arrangement is 30° to 60°.

20. The method according to claim 19, wherein the angle between the extending direction of the light-splitting structure and the row or column direction of the array arrangement is 45°.
